(19) United States
(12) Patent Application Publication
(10) Pub. No.: US 2007/0273024 A1
(43) Pub. Date: Nov. 29, 2007

(54) Cooling System with a Bubble Pump

(76) Inventors: Henry Madsen, Allerod (DK); Henrik Olsen, Fredensborg (DK)

Correspondence Address: VOLENTINE & WHITT PLLC, ONE FREEDOM SQUARE, 11951 FREEDOM DRIVE SUITE 1260, RESTON, VA, 20190, US

(21) Appl. No.: 10/581,921

(22) PCT Filed: Dec. 7, 2004
(86) PCT No.: PCT/DK04/00849

§ 371 Date: Mar. 14, 2007

(30) Foreign Application Priority Data
Dec. 8, 2003 (DK) PA 200301803

(51) Int. Cl. H01L 23/427

(52) U.S. Cl. 257/715; 165/104.29; 257/E21.002

(57) ABSTRACT

The present invention relates to a closed system for cooling without moving mechanical parts and at a low noise level, one or more heat-emitting elements. The system comprises a first heat-receiving part that is adapted to receive heat from the at least one heat-emitting element, a cooling fluid for absorption of heat by heating and evaporation, a bubble pump for generation of a fluid flow in the system, the bubble pump being positioned downstream the first heat-receiving part and moving the cooling fluid towards a radiator emission of heat from the cooling fluid in liquid form to the surroundings, and a condenser for condensing of evaporated cooling fluid and emission of the heat of condensation.

### FIELD OF THE INVENTION

The present invention relates to a closed system for cooling of one or more heat-emitting elements, the system comprising a heat-receiving part adapted to receive heat from a heat-emitting element, a cooling fluid for heat removal, a radiator for emission of heat to the surroundings, and a condenser for condensation of evaporated cooling fluid, wherein the heat emitted by the heat-emitting element is utilized to generate circulation of the cooling fluid.

### BACKGROUND OF THE INVENTION

Many systems with a heat-emitting element have attached cooling systems to avoid excessive heating leading to failure of the heat-emitting element. Such systems may be car engines, refrigerators, electronic and electric components, etc. A cooling unit, particularly for cooling of electronic semiconductor components, is described in US 2003/0 188 858 A1 where the cooling unit comprises a heat-receiving part receiving heat from a heat-emitting element, a cooling liquid transporting heat, and a heat radiator emitting heat to the surroundings. A circulating flow of the cooling liquid is created by decreased density caused by an elevation force of vapor bubbles generated by heat received by the heat-receiving part. The cooling liquid in US 200310 188 858A1 comprises a fluorine compound having a boiling point of 56°, which is considered to be a suitable maximum temperature for electronic components.

### SUMMARY OF THE INVENTION

There is a need for a cooling system with improved performance for cooling of heat-emitting elements.

The above-mentioned and other objects are fulfilled by a cooling system for cooling of at least one heat-emitting element, comprising a first heat-receiving part that is adapted to receive heat from the at least one heat-emitting element, a cooling fluid for absorption of heat by heating and evaporation, a bubble pump for generation of a fluid flow in the system, the bubble pump being positioned downstream the first heat-receiving part and moving the cooling fluid towards a radiator for emission of heat from the cooling fluid in liquid form to the surroundings, and a condenser for condensing of evaporated cooling fluid and emission of the heat of condensation.

It is an important advantage of the present invention that the cooling system does not comprise moving mechanical parts, such as pumps with moving parts. This reduces the cost and increases the reliability of the system.

It is a further advantage of the present invention that the cooling system is substantially silent.

It is a still further advantage of the present invention that the cooling system is capable of removing large amounts of generated heat per unit area, such as more than 15 W/cm², e.g. more than 20 W/cm², e.g. more than 30 W/cm², such as more than 40 W/cm², e.g. more than 50 W/cm², such as about 75 W/cm², etc., causing a temperature increase below 40° C.

Preferably, the bubble pump has an outlet above the liquid level in the system, which substantially prevents reflux of fluid in the system.

In the bubble pump, bubbles generated during heating of the cooling fluid in liquid form at the heat-receiving part combine to larger bubbles moving liquid above the bubbles upward in the bubble pump so that a fluid flow is generated by the motive forces of the bubbles.

It is believed that positioning of the outlet above the liquid level in the system lowers the resistance against the liquid flow experienced by the bubbles in the bubble pump. Thus, provision of a bubble pump with an outlet above the liquid level in the cooling system provides increased circulation of cooling fluid leading to improved cooling capability of the cooling system.

The cooling fluid may comprise a single fluid or two or more fluids.

In a preferred embodiment of the invention, the cooling fluid comprises two fluids, a first fluid with a low boiling point temperature that boils within the operational temperatures of the at least one heat-emitting element, and a second fluid with a higher boiling point that does not reach its boiling point within these temperatures. The bubbles formed by boiling of the first fluid move the second fluid in the bubble pump, thereby generating circulation of the cooling fluid in the system. The second fluid, mainly in liquid form and having a large heat capacity, absorbs and transfers a large amount of heat from the heat-receiving part to the radiator thereby increasing the cooling capability of the system.

The cooling fluid may comprise more than two fluids. The cooling fluids may or may not be soluble within each other.

In liquid form, the second fluid maintains good surface contact with the interior surfaces of the heat-receiving part and the radiator, respectively.

Thus, in the bubble pump, the first fluid with the lowest boiling point is used to pump the second fluid with the higher boiling point into circulation in the cooling system for transfer of heat from the heat-receiving part to the radiator.

Thus, provision of a bubble pump and a cooling fluid with at least two fluids with different boiling points leads to a cooling system with improved efficiency. The fluid with the lowest boiling point is selected so that it boils within the operating temperature of the heat-emitting element. The fluid with the higher boiling point is selected so that it remains substantially in its liquid form and does not reach its boiling point within the intended operating temperatures of the heat-emitting elements. In the bubble pump, the bubbles originally generated in the heat-receiving part moves the liquid with the higher boiling point thereby generating a liquid flow through the heat-receiving part. The liquid flow increases heat removal from the heat-receiving part due to the high heat capacity of the fluid with the high boiling point.

Further, the liquid flow removes bubbles generated in the heat-receiving part while they are still small thereby avoiding that bubbles isolate the heat-receiving part from the liquid part of the cooling fluid, which would lower heat transfer from the heat-emitting element to the cooling fluid.

Thus, a controlled and enhanced cooling is obtained compared to a similar cooling system with a cooling fluid with a single fluid. The resulting cooling effect is obtained by the combination of absorbing heat by evaporation of the fluid with the lowest boiling point, which evaporates completely or partly, and by heating and removal, mainly without evaporation, of the one or more fluids with a higher boiling point. The fluid(s) with the higher boiling point(s) typically evaporates to a limited extent, however the fluid flow removes heat from the heat-receiving part.

Since the fluid with the highest boiling point typically evaporates to a limited extent only, dry boiling of the system is avoided under intended operational conditions.

The condenser and the radiator may form an integrated unit such that condensate and cooling fluid mixture are mixed continuously as the evaporated fluid is condensed. If the condenser and the radiator form separate units, the condensed fluid is mixed with the other fluid(s) after the condensation. Thus, the original concentration ratio is substantially reestablished independent of the design of the condenser and the radiator.

The radiator and/or the condenser may be cooled utilizing natural convection, forced convection, or alternatively by an active cooling system, such as a compressor cooler. For example, a power supply unit fan may also be used for forced convection of the cooling system.

According to a preferred embodiment of the invention, the cooling fluid comprises a first fluid with a low boiling point and a second fluid with a high boiling point.

Preferably, the first fluid may comprise ethanol, methanol, acetone, ether, propane, etc., or other fluids also having suitable thermal and physical properties.

In a presently preferred embodiment, the first fluid is ethanol, the cooling fluid comprising between 4% and 96% volume by volume of ethanol, such as from 15% to 45%, from 30% to 40%, preferably about 37%.

The first fluid may be any liquid, which easily vaporizes and which is miscible with or absorbed in water. Such other options are ammonia, the fluorine compounds 3M® FC-72 and 3M® FC 82, and others.

Preferably, the second fluid is water. Water has the advantages that it is cheap, is readily available, and a possible leak will not lead to contamination.

According to a preferred embodiment a specific pressure is applied to the cooling system. Thereby the boiling point temperature of the first fluid may be adjusted in a simple way. This has the effect that a wide range of different cooling fluids may be employed for cooling to a given maximum temperature. It is understood that the specific pressure applied to the system is the system pressure when the system is not operating, i.e. when substantially all parts of the system have the same temperature, e.g. room temperature. This specific pressure may advantageously be adjusted during manufacture of the cooling system. When the cooling system is in operation, the cooling fluid will be heated, and typically, the pressure in the system changes.

According to a preferred embodiment the pressure of the cooling system is adjusted in such a way that the boiling point of the first cooling fluid resides within a desired operating temperature range of the cooling system. The pressure in the system is preferably substantially equal to the saturation pressure of the cooling fluid at the actual temperature.

Preferably, the cooling system is evacuated before entrance of the cooling fluid into the cooling system to avoid presence of air or any other undesired gases in the cooling system. Air or undesired gases may react with the selected cooling fluids, and presence of undesired gases may decrease the efficiency of the system by occupying volume in the cooling system. Upon evacuation, the cooling fluid is entered into the cooling system and the system is hermetically sealed.

According to a preferred embodiment of the present invention, the internal volume in the cooling system is substantially filled with cooling fluid in combined liquid and gaseous form, i.e. the content of non-condensable gases, such as N₂, O₂, CO₂, H₂, etc., or other contaminants is minimized, e.g. the content is less than 10% by volume of the internal volume, such as less than 5%, less than 3%, or less than 1% of the internal volume.

The efficiency of the cooling system is believed to be the higher the lower the content of non-condensable gases, since non-condensable gases do not contribute to the heat transfer from the heat-receiving part(s) to the condenser and/or radiator.

The term non-condensable gases denotes gases, which are not condensable within the operating temperature and operating pressure of the cooling system.

To prevent formation of non-condensable gases after filling of cooling fluid, the cooling fluid may comprise a corrosion inhibitor.

It should be noted that the specific pressure may be equal to atmospheric pressure, larger than atmospheric pressure as well as lower than atmospheric pressure depending on the selected cooling fluid and the desired maximum operating temperature of the heat-emitting elements.

The flexibility of pressure adjustment is advantageous, since it may be difficult to find a cooling fluid having the desired boiling point. In certain cases such a cooling fluid may exist, but may have other disadvantages such as high cost, toxicity, etc.

The bubble pump may comprise a substantially tube-shaped part.

Preferably, the tube-shaped part extends substantially linearly in its longitudinal direction.

In one embodiment of the invention, an outlet of the bubble pump is positioned in the radiator in such a way that the outlet of the bubble pump during operation of the cooling system resides above the liquid level in the radiator. As already mentioned, this enhances the efficiency of the bubble pump, since reflux flow of fluid back into the bubble pump is avoided. It is further believed that this positioning of the outlet lowers the resistance against the liquid flow experienced by the bubbles in the bubble pump. Thereby the circulating flow in the system is increased, providing improved heat-transfer and thus improved cooling.

The outlet of the bubble pump may be formed to facilitate the outflow of liquid from the bubble pump, e.g. the outlet may be chamfered.

The tube-shaped part of the bubble pump preferably has a substantially circular or oval cross-section. The efficiency of the bubble pump, i.e. the amount of liquid transported through the bubble pump as a function of time, is i.a. determined by the internal diameter of the substantially tube-shaped part of the bubble pump and the properties of the fluid or fluids to be pumped, such as amount and size of the vapor bubbles, viscosity of the fluid(s), etc.

In a preferred embodiment of the present invention for removing up to around 250 W heat power, the bubble pump may have an internal diameter ranging from 3 to 20 mm, such as from 6 to 15 mm, from 8 to 12 mm, e.g. equal to app. 10 mm.

The internal diameter of the bubble pump must be sufficiently large to provide a suitable flow capacity. Preferably, the vapor bubbles in the bubble pump attains a size with a cross-section substantially equal to the internal diameter of the bubble pump to provide suitable pumping of liquid through the bubble pump.

The length of the bubble pump may be adjusted to obtain a desired flow capacity. Preferably, the length is larger than the internal diameter of the bubble pump. Preferably, the length of the bubble pump ranges from 0.5 to 20 cm, such as from 1 to 15 cm, from 2 to 10 cm, from 3 to 8 cm, or around 5 cm.

Typically, stationary devices with a heat-emitting element to be cooled are operated in an orientation that remains substantially unchanged. In a portable computer, or other portable, electronic units, the orientation of the cooling system typically changes when the portable unit is transported, but typically, the unit will be operated in certain orientations.

The cooling system may be adapted for cooling of more than one heat-emitting element. For example, the heat-receiving part may be of a sufficient size to receive heat from more than one heat-emitting element, and/or the cooling system may comprise more than one heat-receiving part. In this case, the heat-receiving parts may each receive heat from one or more heat-emitting elements. The fact that more than one heat-emitting element may be positioned along the heat-receiving part of the cooling system may provide an advantage regarding to economy of space and/or regarding enhanced circulation of the cooling fluid.

The heat-receiving part may comprise a heat-exchanging surface, which is adapted to thermally contact the heat-emitting element. Hereby the cooling system is adapted to receive heat from a heat-emitting element in thermal contact with the heat-exchanging surface. The heat-exchanging surface is typically shaped to correspond to the shape of the heat-emitting element(s) to be cooled. Preferably, the heat-exchanging surface of the heat-receiving element(s) of the cooling system is made of a heat-conducting material, such as aluminum, copper, silver, gold, or alloys comprising one or more of these materials.

Advantageously, the heat-emitting element may be integrated with the heat-receiving part to be in direct contact with the cooling fluid of the cooling system. Hereby, the heat exchange between the heat-emitting element to be cooled and the heat-receiving part is optimized. The integration between the heat-emitting element to be cooled and the heat-receiving part of the cooling system may advantageously be performed during the manufacture of the cooling system so that the cooling system is adapted to the heat-emitting element to be cooled and its possible electrical connections to other elements.

The heat-receiving part of the cooling system may comprise a plurality of separated liquid chambers. The heat-receiving part may for example be made as a closed, extruded profile forming a single chamber or split into a plurality of chambers, and the ends of the profile may be connected to the other parts of the cooling system by means of manifolds. In one embodiment, the extruded profile may function wholly or partly as the pipe system and/or the bubble pump. In this embodiment one or more heat-receiving parts may further form an integrated part of the extruded profile.

The cooling system is preferably made of a diffusion tight material. By the expression “diffusion tight material” is understood a material that does not entail larger diffusion between the cooling system and the surroundings during the intended lifetime of the system than can be allowed for the system to operate as intended during its entire intended lifetime. If the cooling system is employed in computers, the intended lifetime will typically be in the order of 4-5 years and in special cases down to 2 years or up to 10 years. If different parts of the cooling system are made of different materials, all materials as well as their connections must be diffusion tight. Suitable materials may be copper, silver, aluminum, iron or alloys containing one or more of these materials. Moreover, one or more parts of the cooling system may be made of plastic material, provided that it is made diffusion tight according to the above-mentioned definition of the expression. A metal layer forming part of the plastic material may ensure this, such metal layer may for example be vapor deposited onto the plastic material.

The cooling system may further comprise a window of a material that has a larger permeability for undesired gases than the material(s) of the remaining parts of the cooling system. For example, the window may be hydrogen permeable, and made of e.g. nickel, or an alloy thereof, e.g. an iron-nickel alloy, or palladium or an alloy thereof, e.g. a silver-palladium alloy. Hereby, the undesired gasses are removed into the atmosphere by diffusion through the window. The window may be positioned adjacent to a connecting piece for entering the cooling fluid into the cooling system. The diffusion of undesired gases may then take place for a period after filling of the cooling system, and at the end of the period the window may be removed together with the connecting piece during final closing of the cooling system.

The invention furthermore relates to an electronic device having one or more elements to be cooled during the operation of the electronic device, the electronic device comprising a cooling system according to the invention.

The invention also relates to use of the closed cooling system for cooling of electronic components. Such components may for example be microchips, CPU's, semiconductor devices, etc. in computers or other electronic devices. In particular in the field of cooling of electronic components, the cooling system according to the invention is advantageous, as it is a low noise unit, has no mechanically movable elements and as it is started automatically by the heat, which the electronic components emits.

It should be noted that the expression “cooling fluid” denotes a fluid that is used for cooling, and which either consists of a single fluid or a mixture of two or more fluids.

Throughout the present description, a single fluid denotes a fluid with purity of more than 96% volume by volume.

Furthermore, it should be noted that the cooling system may comprise more than one condenser and/or more than one radiator. In such cases the condensers and radiators respectively may be arranged in series or in parallel or a combination thereof.

The invention will now be described in further detail with reference to the figures of the drawing, wherein

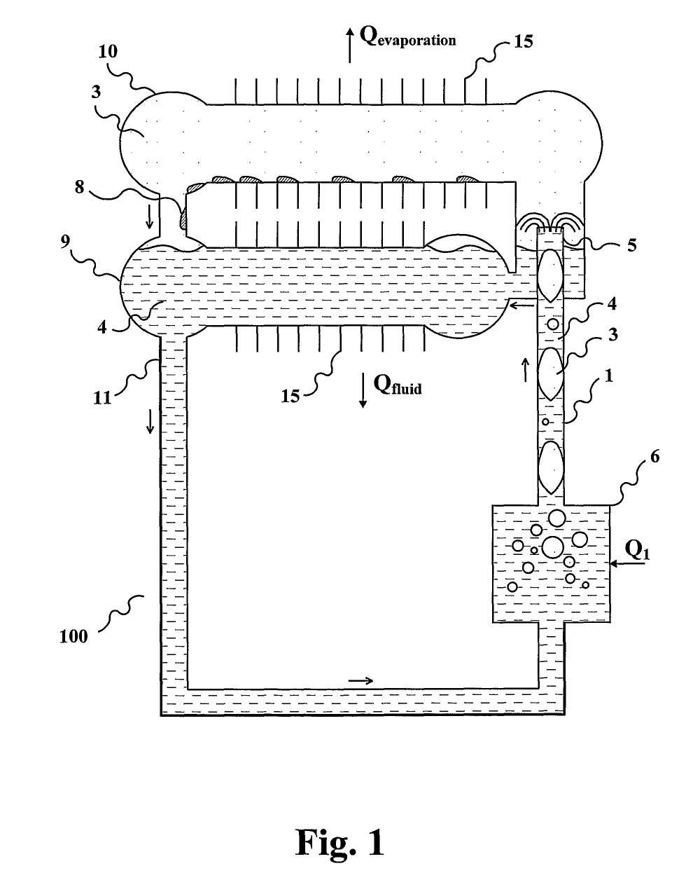

FIG. 1 schematically illustrates a cooling system according to a preferred embodiment of the invention

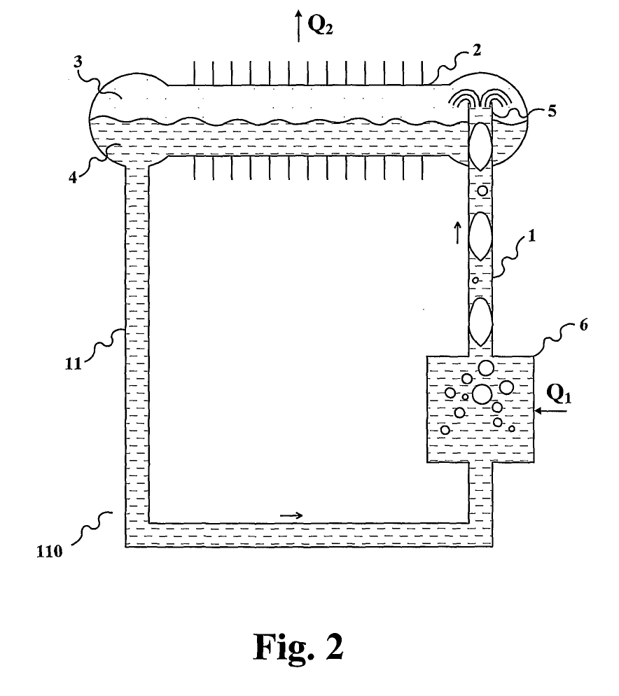

FIG. 2 schematically illustrates a second embodiment of the invention,

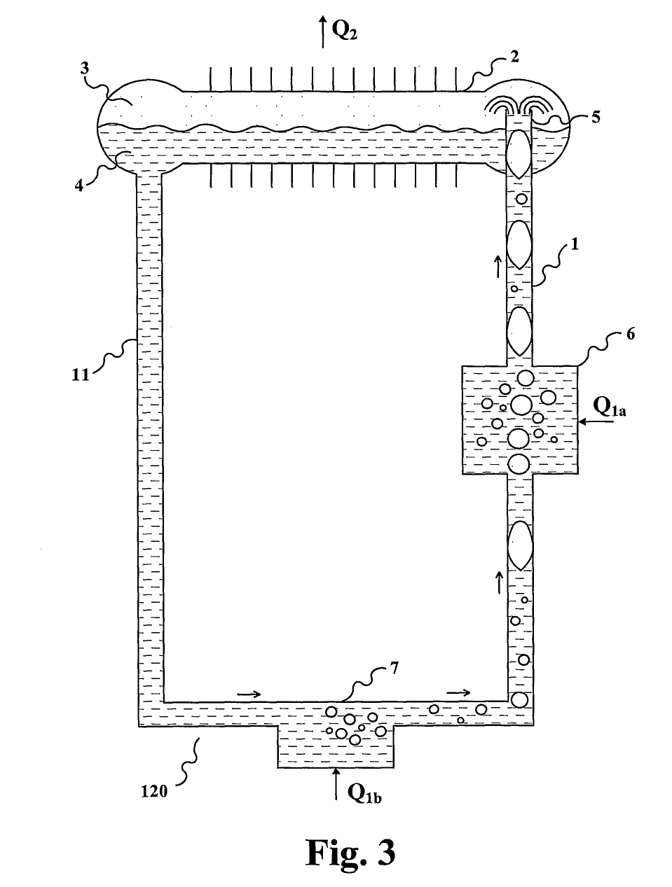

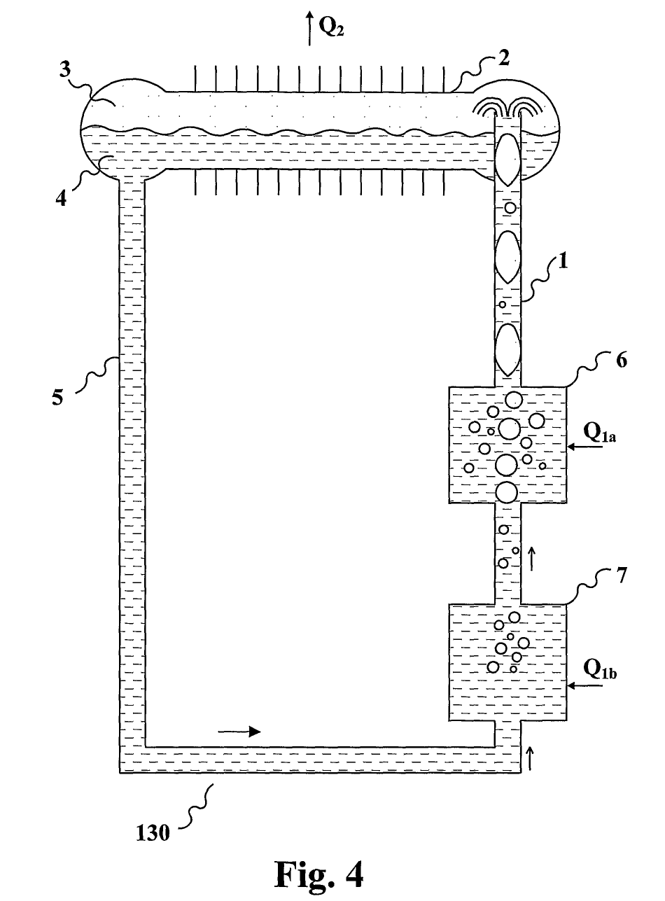

FIGS. 3 and 4 illustrate a third and a fourth embodiment of the invention,

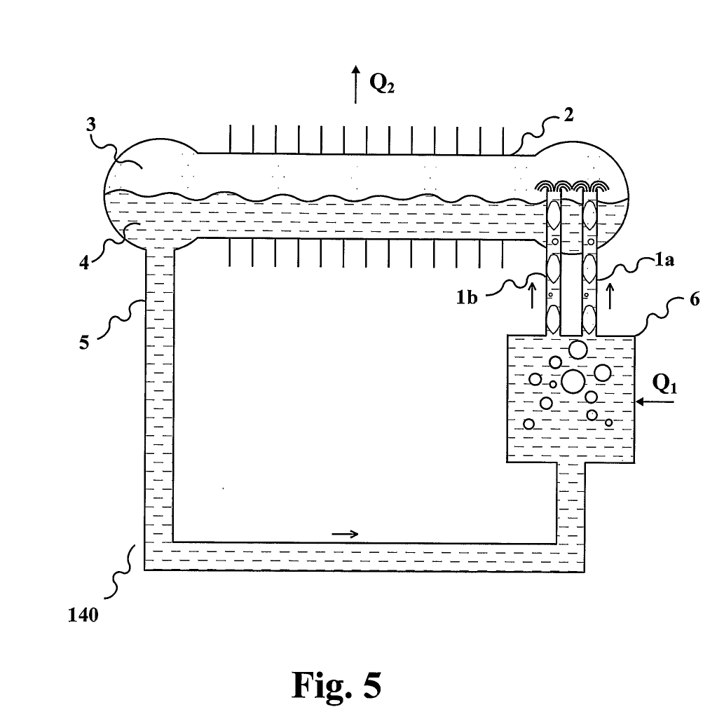

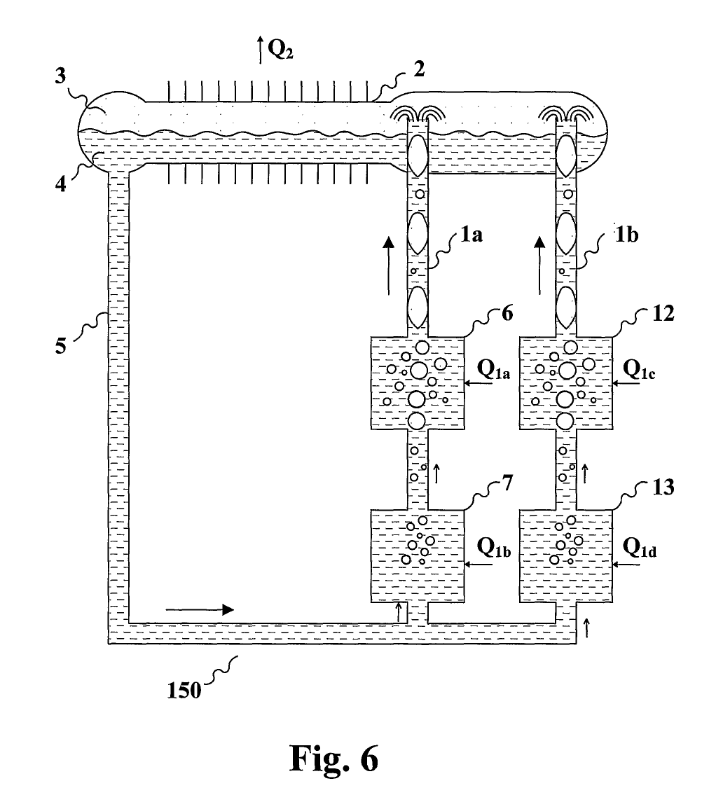

FIGS. 5 and 6 schematically illustrate embodiments of the cooling system with a plurality of components in parallel,

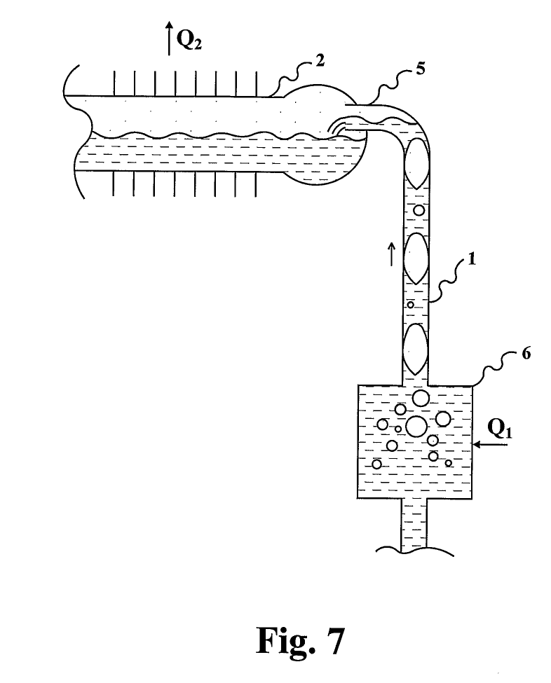

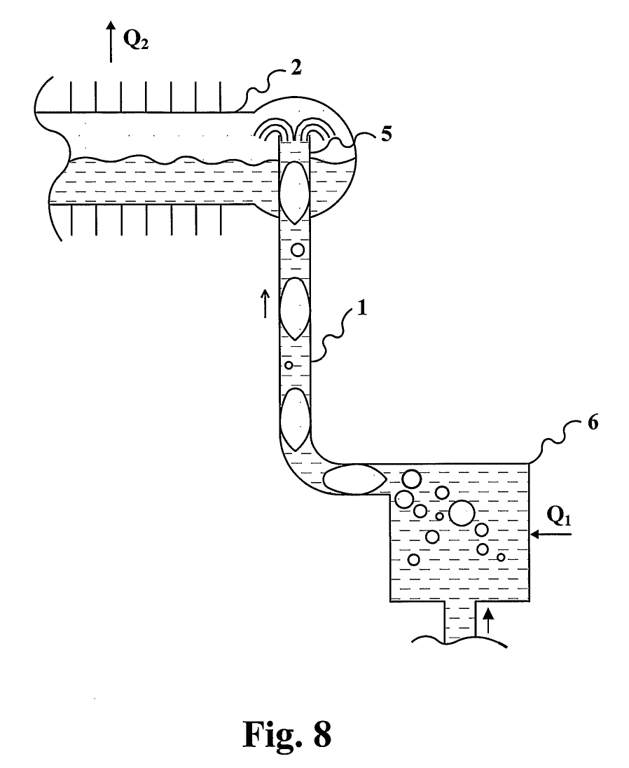

FIGS. 7 and 8 schematically illustrate different embodiments of the outlet of a bubble pump in a cooling system according to the invention,

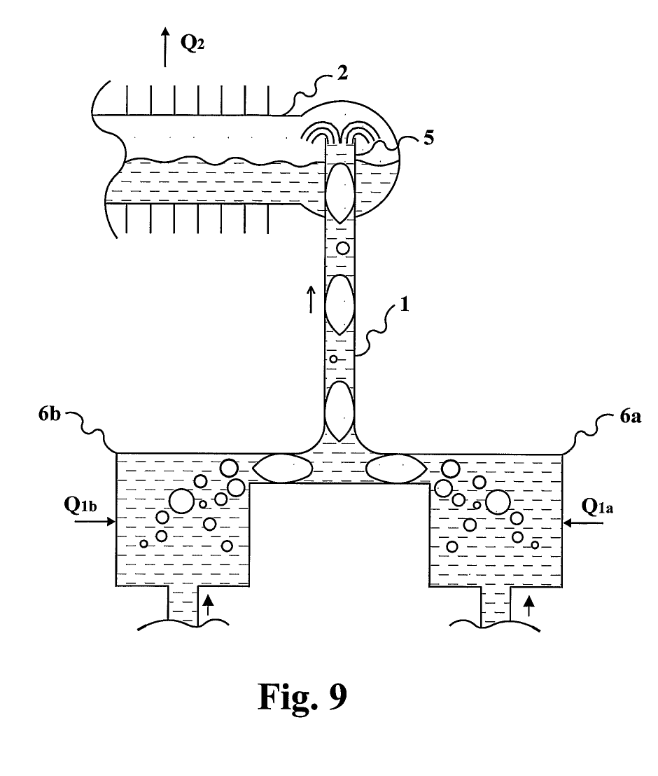

FIG. 9 schematically illustrates an embodiment of the present invention with two heat-receiving parts in parallel and one bubble pump, and

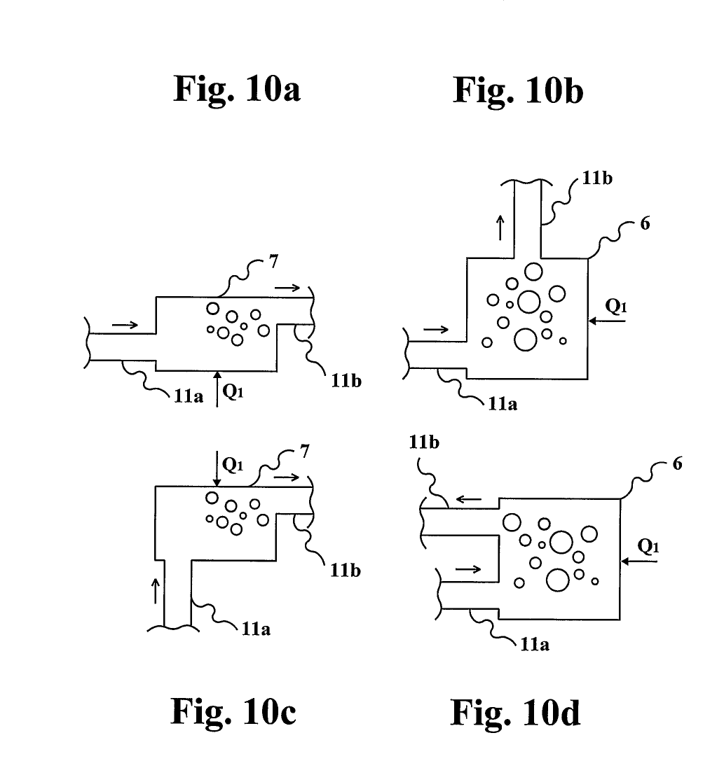

FIGS. 10a-d schematically illustrate different embodiments of a heat-receiving part of the cooling system,

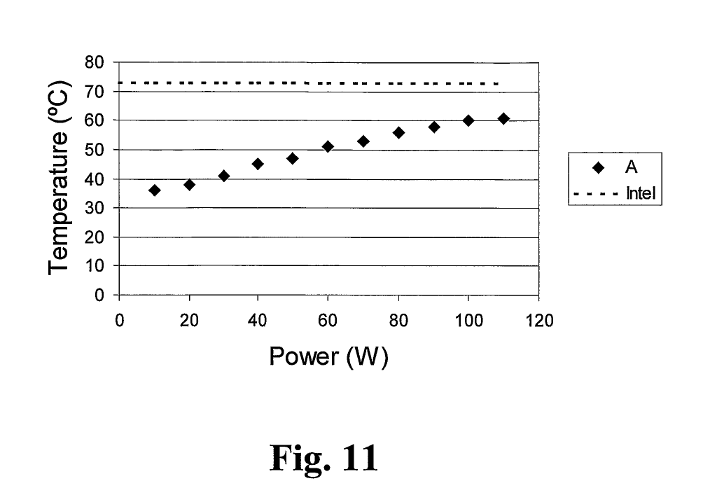

FIG. 11 is a plot of test results for an embodiment of the present invention.

The same reference number denotes the same elements in the different embodiments of the figures, and elements that are explained in connection with one figure will not be explained further in connection with other figures.

FIG. 1 illustrates a cooling system 100 with a circulating cooling fluid 4. The cooling system 100 is self-circulating, since a circulating flow of the cooling fluid 4 is created by means of a bubble pump 1 generating an elevation force of bubbles of evaporated cooling fluid 3 created by heat received by a first heat-receiving part 6. The cooling fluid is a mixture of two or more fluids having different boiling points. A first fluid has the lowest boiling point. The first fluid is selected with a boiling point suitable for cooling of the heat-emitting elements. The cooling system is a closed system with a specific pressure causing the first fluid with the low boiling point to boil at a desired temperature. The horizontal, broken lines indicate cooling fluid 4 in liquid state, while the circles or the ovals 3 indicate bubbles, i.e. cooling fluid in gaseous state within liquid cooling fluid 4.

The cooling system receives heat energy Q₁ supplied to the first heat-receiving part 6. Hereby, the first fluid is heated to its boiling point and a part of it evaporates. In the bubble pump 1, the evaporated cooling fluid rises in the form of bubbles. Between the bubbles there will be heated, liquid cooling fluid, which is transported up through the bubble pump by means of the rising bubbles creating circulation of the cooling fluid.

In the bubble pump, bubbles created during heating of the cooling fluid in liquid form at the heat-receiving part combine to larger bubbles that substantially fill up the cross-section of the bubble pump thereby pushing liquid above the bubbles upward in the bubble pump. In this embodiment, bubbles and liquid move at substantially the same velocity in the bubble pump.

The fluid leaves the bubble pump 1 at an outlet 5, comprising evaporated (i.e. gaseous) cooling fluid and heated, liquid cooling fluid. The evaporated cooling fluid flows into a condenser 10, which is adapted to conduct heat of evaporation Qₑᵥₐₚₒᵣₐₜᵢₒₙ to the surroundings, whereby the evaporated cooling fluid condenses to condensed fluid 8. The condensed liquid may be cooled further. The heated, liquid cooling fluid flows to the radiator 9, where it is cooled and emits heat energy Q_{fluid} to the surroundings. Thus, the heat Q₂ emitted to the surroundings from the condenser and the radiator in combination is equal to Q₂=Qₑᵥₐₚₒᵣₐₜᵢₒₙ+Q_{fluid}.

In the equilibrium state of the cooling system, the heat Q1, which the system receives, equals the heat Q₂, which the radiator and the condenser in combination emit to the surroundings.

The radiator 9 and the condenser 10 are also connected to each other downstream after heat emission so that condensed fluid 8 and cooled cooling fluid 4 are combined after the heat emission.

It should be noted that the outlet 5 of the bubble pump is positioned above the level of the liquid in the system during operation as shown in FIG. 1. This increases circulation of cooling fluid in the system. Moreover, it should be noted that the bubble pump is the part of the cooling system that is between the first heat-receiving part 6 and the outlet 5.

The radiator 9 and the condenser 10 may be cooled by natural convection, forced convection, e.g. by a fan, or alternatively by means of an active cooling system, such as a compressor cooler.

The first heat-receiving part 6 may also be designed in different suitable ways, the first heat-receiving part 6 having a contact surface for transfer of heat from the heat-emitting element, where the contact surface is designed to fit the heat-emitting element. If the heat-emitting element has a plane surface, the heat-receiving part will typically also be designed with a plane surface to fit the heat-emitting element. Besides, the inner surface of the heat-receiving part is suitably shaped to ensure good heat contact with the cooling fluid, for example by means of fins, rods, or the like. The first heat-receiving part 6 may also be designed so that the heat-emitting component is positioned directly in contact with the cooling fluid (not shown).

After combination of the condensed cooling fluid and the cooled cooling fluid from the condenser 10 and the radiator 9, the combined cooling fluid is guided back to the first heat-receiving part 6 through a pipe system 11 so that the cooling fluid continuously circulates in the closed cooling system. The arrows along the pipe system indicate the direction of the flow of the cooling fluid in the system during operation.

The outer part of the condenser 10 and the radiator 9 is provided with ribs 15 to enhance heat exchange with the surroundings. Moreover, the interior of the condenser 10 and/or the radiator 9, as well as the interior of the first heat-receiving part 6 may be provided with ribs, fins, or the like to enhance heat exchange.

In FIG. 1, the first heat-receiving part 6 is positioned at a vertical pipe section; however it could also be positioned at a horizontal part of the pipe system. Because the bubble pump has an outlet 5 positioned over the level of liquid in the system, the circulation would be driven in the direction of the arrows in FIG. 1 even with the first heat-receiving part 6 positioned at a horizontal part of the pipe system.

FIG. 2 shows an alternative cooling system 110 according to the invention. This cooling system 110 also comprises a first heat-receiving part 6, a bubble pump 1 having an outlet 5, and a pipe system 11. The cooling system 110 also comprises a cooling fluid, whereof a part may be gaseous (evaporated) 3 and a part may be in liquid state 4 during operation. In FIG. 2 the radiator and condenser of the cooling system are integrated into one unit 2 such that condensate and cooling fluid are continuously mixed as the gas 3 condenses. Heat energy from condensing of vapor and cooling of liquid contribute to the heat energy Q₂ that is emitted to the surroundings.

FIGS. 3 and 4 illustrate cooling systems 120 and 130, respectively, with two heat-receiving parts 6 and 7. In FIG. 3 the first heat-receiving part 6 is positioned at a vertical part of the pipe system. In both FIG. 3 and 4, the cooling fluid circulates in the direction of the arrows. The heat-receiving parts 6, 7 could be positioned at an arbitrary part of the pipe system. It should be noted that the bubble pump in FIGS. 3 and 4 is the part of the pipe system between the first heat-receiving part 6 and the outlet of the pipe 5.

In FIGS. 3 and 4 the size of the bubbles of evaporated cooling fluid is indicated larger in the direction of the circulation from the second heat-receiving part 7 to the first heat-receiving part 6 and up to the outlet 5 of the bubble pump, while there are no bubbles upstream the second heat-receiving part 7. This is to illustrate that the cooling fluid upstream the second heat-receiving part 7 is in liquid state, substantially, while a part of the cooling fluid evaporates on passage through the second heat-receiving part 7 and yet a part of the cooling fluid evaporates on passage through the first heat-receiving part 6.

The second heat-receiving part 7 receives the heat Q_{1b} from a heat-emitting element, while the first heat-receiving part 6 receives the heat Q₁ₐ from a heat-emitting element, which may be the same element as emits heat to the second heat-receiving part 7 or, which may be another heat-emitting element. The cooling system may comprise more than two heat-receiving parts positioned along the horizontal and/or vertical parts of the pipe system.

FIGS. 5 and 6 schematically illustrate cooling systems 140 and 150, respectively, with a plurality of components positioned in parallel. In FIG. 5, the cooling system comprises a heat-receiving part 6 receiving the heat Q₁. The bubble pump 1 is split into two pipes 1a and 1b, each discharging into the integrated radiator and condenser 2. In FIG. 6, the cooling system 150 comprises two parallel bubble pumps 1a and 1b, and two heat-receiving parts 6,7 upstream the first bubble pump 1a receiving the heat Q₁ₐ, Q_{1b}, respectively. Two heat-receiving parts 12, 13 receiving the heat Q_{1c}, Q_{1d}, respectively, are positioned in series upstream the second bubble pump 1b and parallel to the bubble pump 1a and the heat-receiving parts 6 and 7. In equilibrium, the heat Q₁=Q₁ₐ+Q_{1b}+Q_{1c}+Q_{1d} received by the cooling system is equal to the heat Q₂ emitted by the radiator and the condenser in combination.

By positioning of a plurality of heat-receiving parts on the same flow path in the system, i.e. upstream in relation to the same bubble pump, the distribution of the heat that contributes to heating and evaporation, respectively, will be different from element to element. In contrast to conventional cooling systems with a forced liquid flow wherein heat emitting elements positioned in series along the cooling system operate at increasing temperatures in the direction of the flow, the heat-receiving parts positioned in series in the cooling system according to the present invention operate at a maximum temperature that is equal to the boiling point temperature of the fluid with the lowest boiling point. Thus, the cooling system according to the present invention does not exhibit the temperature accumulating effect of conventional cooling systems.

Further, the heat-receiving part positioned furthest upstream in relation to the bubble pump in a flow path in the system may be cooled to a lower temperature than downstream heat-receiving part(s) namely to a temperature below the boiling point of the fluid with the lowest boiling point temperature. It is furthermore noted that the circulation flow velocity in the cooling system typically increases by use of a plurality of heat-receiving parts.

FIGS. 7 and 8 schematically illustrate alternative designs of the outlet 5 of a bubble pump 1 in a cooling system during operation. In FIG. 7 the outlet 5 of the bubble pump 1 is horizontal and above the level of liquid in the integrated radiator and condenser 2. In FIG. 8, the outlet 5 is vertical and still above the level of liquid in the integrated radiator and condenser 2. However, although the direction of the outlet 5 of the bubble pump 1 could be arbitrary, the outlet 5 is advantageously positioned above the level of liquid in the integrated radiator and condenser 2. Furthermore, the outlet 5 of the bubble pump 1 may be chamfered at an arbitrary desired angle.

FIG. 9 schematically illustrates a part of an embodiment of the present invention with two heat-receiving parts 6a and 6b in parallel feeding one bubble pump.

FIGS. 10a-d schematically illustrate different embodiments of inlet and outlet of a heat-receiving part of the cooling system. Upward on the figures corresponds to upward in the system in its operating position. FIGS. 10a-d show heat-receiving parts 6 or 7, each of which is connected with an inlet pipe 11a and an outlet pipe 11b. In all the FIGS. 10a-d, the cooling fluid flows through the heat-receiving part 6, 7 in the direction of the arrows during operation of the cooling system.

In FIG. 10a, the inlet pipe 11a and the outlet pipe 11b extend horizontally. The inlet pipe 11a is connected to the left side of the heat-receiving part 7, and the outlet pipe 11b is connected to the right side of the heat-receiving part 7. The inlet pipe 11a is positioned below the outlet pipe 11b. In FIG. 10b, the inlet pipe 11 a also extends horizontally and is positioned to the left of the heat-receiving part 6. The outlet pipe 11b extends vertically and is connected to the top of the heat-receiving part. In FIG. 10c, the inlet pipe 11a extends vertically and is connected to the bottom of the heat-receiving part 7, while the outlet pipe 11b extends horizontally and is connected to the right upper side of the heat-receiving part. Finally, both the inlet pipe 11a and the outlet pipe 11b in FIG. 10d extend horizontally and are connected to the left side of the heat-receiving part 6 as viewed in the plane of the drawing. In FIG. 10d, the outlet pipe 11b is positioned above the inlet pipe 11a. It should be noted that FIGS. 10a-d illustrate examples of embodiments of the positioning and orientation of inlet and outlet pipes to the heat-receiving part of the cooling system. Although the inlet and outlet pipes in the illustrated examples are either vertical or horizontal, they may also be oblique. It is preferred, but is not strictly necessary for the system to function that the outlet from a heat-receiving part of the cooling system is positioned at the same level or higher than the inlet during operation whereby bubbles of evaporated cooling fluid move naturally toward the outlet. It is further noted that the different embodiments of inlet and outlet pipes to/from a heat-receiving part of the cooling system may be combined arbitrarily as desired, when the cooling system comprises more than one heat-receiving part.

FIG. 11 shows test results obtained for the embodiment illustrated in FIG. 2. A heat-emitting element generating heat power from 10 to 170 W on a heat-receiving surface of 1.50 cm² was cooled by a cooling system according to the present invention. Measurements of corresponding values of temperature and generated heat power are plotted as data points A. It is seen that the cooling system is capable of cooling a heat-emitting element to temperatures below Intel's Thermal Design Power of 73° C. at effects of from 10 to 170 W. As indicated in the plot, 110 W heat power was removed from a surface of 1.50 cm², which corresponds to a heat density of 75 W/cm² at a temperature of 67° C. Low noise forced cooling was applied. The noise generated from the cooling system was less than 30 dB(A).

It should be noted that arbitrary features of the different embodiments shown in the different figures could be combined if desired.

Moreover, it should be noted that the pipes of the cooling system may be made of rigid pipes, or pipes that are flexible either due to their design or due to their material. Furthermore, the pipes of the cooling system and pipes in condenser/radiator may form a suitable arbitrary profile, e.g. round, oval, rectangular, quadratic, or a combination of these, and the internal volume of the profile may constitute a single chamber or may be divided into a plurality of chambers. Likewise the orientation of the pipes of the cooling system may be oblique, even though all pipes in the figures are shown either vertical or horizontal.

Even though the heat-receiving element in the figures is shown to be quadrangular, any heat-receiving part, seen from all directions, may be made in different shapes, such as round, oval, rectangular, quadratic or a combination of these. However, it is preferred that the heat-receiving part has a contact surface, which is adapted to the shape of the heat-emitting element; typically the contact surface will be plane. It should be noted that the contact surface of the heat-receiving part is the part of the heat-exchanging surface of the heat-receiving part, which is in contact with the heat-emitting element(s).

The inside of the heat-receiving element may be provided with ribs, rods, etc. to enhance the contact area between the cooling fluid and the heat-receiving element. These area-enhancing elements may for example be brazed elements or may be produced by e.g. sintering, casting, pressing, extrusion, or chip cutting.

The system may further be provided with a non-return valve (not shown) in the pipe system so that a flow may be established in only one direction in the cooling system. Such a non-return valve will suitably be positioned upstream to the (first) heat-receiving part of the cooling system.

The cooling system according to the invention may advantageously be employed, where low noise cooling is desired, e.g. in portable or stationary computers, electronics, overhead projectors, beamers, air condition systems, etc.

1-16. (canceled)

17. A cooling system for cooling of at least one heat-emitting element, comprising
a first heat-receiving part that is adapted to receive heat from the at least one-heat emitting element,
a cooling fluid for absorption of heat by heating and evaporation,
characterized in that the system is hermetically sealed and further comprises
a bubble pump with a tube-shaped part for generation of a fluid flow in the system by the motive forces of bubbles moving liquid cooling fluid at substantially the same velocity as the bubbles in the tube-shaped part, the tube-shaped part being positioned downstream the first heat-receiving part and moving the cooling fluid towards a radiator for emission of heat from the cooling fluid in liquid form to the surroundings, and
a condenser for condensing of evaporated cooling fluid and emission of the heat of condensation.

18. The cooling system according to claim 17, wherein the bubble pump has an outlet wherein the outlet during operation of the cooling system is positioned above the liquid level of the system.

19. The cooling system according to claim 17, further comprising a second heat-receiving part for accommodation of a heat-emitting element.

20. The cooling system according to claim 17, further comprising a plurality of bubble pumps.

21. The cooling system according to claim 20, wherein at least some of the bubble pumps are connected in series.

22. The cooling system according to claim 20, wherein at least some of the bubble pumps are connected in parallel.

23. The cooling system according to claim 17, wherein the cooling fluid comprises at least two fluids with different boiling points.

24. The cooling system according to claim 17, wherein a first fluid in the cooling fluid is selected from the group of ethanol, methanol, acetone, ether and propane.

25. The cooling system according to claim 17, wherein a second fluid in the cooling fluid is water.

26. The cooling system according to claim 17, wherein the pressure in the cooling system is adjusted to a desired pressure.

27. The cooling system according to claim 26, wherein the pressure is adjusted so that the lowest boiling temperature of the fluids substantially equals the desired operating temperature of the at least one heat-emitting element.

28. The cooling system according to claim 26, wherein the pressure in the cooling system is lower than the atmospheric pressure.

29. The cooling system according to claim 17, wherein a heat-emitting element is integrated in the heat-receiving part and is in direct contact with the cooling fluid in the cooling system.

30. The cooling system according to claim 17, wherein the heat-receiving part comprises a plurality of separated liquid chambers.

31. An electronic device having one or more elements to be cooled during the operation of the electronic device, wherein the electronic device comprises the cooling system according to claim 17.

32. Use of the cooling system according to claim 17, for cooling of electronic components.
